(19) United States
(12) Patent Application Publication
(10) Pub. No.: US 2010/0320387 A1
(43) Pub. Date: Dec. 23, 2010

(54) QUANTUM UNCOOLED INFRA-RED PHOTO-DETECTOR

(75) Inventors: Valery Garber, Yokneam Illit (IL); Emamuel Baskin, Haifa (IL); Alex Fayer, Herzliya (IL)

Correspondence Address: SIMON KAHN - PYI Tech, Ltd.;c/o LANDONIP, INC, 1725 Jamieson Avenue, ALEXANDRIA, VA, 22314, US

(73) Assignee: D.C. SIRICA LTD., Nesher (IL)

(21) Appl. No.: 12/866,036

(22) PCT Filed: Aug. 5, 2008
(86) PCT No.: PCT/IL08/01072

§ 371 Date: Aug. 4, 2010

(30) Foreign Application Priority Data
Feb. 4, 2008 (IL) 189254

(51) Int. Cl. H01L 31/105; H01L 31/0232

(52) U.S. Cl. 250/338.4; 257/458; 257/432; 250/200; 257/E31.061; 257/E31.127

(57) ABSTRACT

A photo-detector comprising: a p-doped semiconductor layer; an n-doped semiconductor layer juxtaposed with the p-doped semiconductor layer; one of an intrinsic amorphous silicon layer sandwiched between the p-doped semiconductor layer and the n-doped semiconductor layer and a depletion region formed between the p-doped semiconductor layer juxtaposed with the n-doped semiconductor layer; a plurality of mesoscopic sized particles within the one of the intrinsic amorphous silicon layer sandwiched between the p-doped semiconductor layer and the n-doped semiconductor layer and the depletion region formed between the p-doped semiconductor layer juxtaposed with the n-doped semiconductor layer. A source of pumping light is provided and arranged to be received at the mesoscopic sized particles thereby generating free carriers confined in the mesoscopic sized particles. Received light of a target waveband releases the carriers from confinement which is detected as a flow of current.

### BACKGROUND

The invention relates generally to the field of infra-red photo-detectors and in particular to a PN or PIN junction based infra-red photo-detector comprising a pumping light and a plurality of mesoscopic sized particles within the intrinsic or depletion region.

Photo-detectors are used in a wide variety of applications including imaging. A specific type of photo-detector sensitive to the infra-red (IR) wavelengths of light is also known as an IR detector. IR covers a broad range of wavelengths, however many materials and detectors known to the prior art are only sensitive to a certain range of wavelengths. As a result, the IR band is further divided into sub-bands such as near IR defined conventionally as comprising the wavelengths between 0.75-1.4 μm; short wavelength IR defined conventionally as comprising the wavelengths between 1.3-3 μm; mid wavelength IR (MWIR) defined conventionally as comprising the wavelengths between 3-8 μm; long wavelength IR (LWIR) defined conventionally as comprising the wavelengths between 8-15 μm; and far IR defined conventionally as comprising the wavelengths between 15-1,000 μm. IR in the range of 5 μm to 8 μm is not well transmitted in the atmosphere and thus for many IR detection applications the atmospheric windows (3-5 μm) and (8-14 μm) are of primary practical interest.

Prior art quantum JR photo-detectors are typically limited by thermal generation of free charge carriers resulting in a dark-thermal current which disturbs the IR detection process as noise. In the thermal equilibrium exhibited by prior art devices the energy exchange between the device material subsystems, i.e. between the charge carriers (electron/holes) and the atomic lattice, is very effective. As a consequence the temperature of the charge carriers is defined by the temperature of the surrounding atomic lattice. In order to reduce the dark-thermal current noise the temperature of the charge carriers is reduced, which due to the aforementioned thermal equilibrium, is equivalently accomplished by cooling the entire device to cryogenic temperatures.

IR detectors known to the prior art, capable of sensing IR radiation in the MWIR and LWIR sub-bands, are largely divided into two categories based on the principles of their operation, known as thermal and photon or quantum detectors. Each of the above categories contains several subcategories that vary in their material composition, operating mechanism, operating requirements and performance.

Thermal IR detectors, which are typically operational at room temperature and thus do not require expensive cooling, include devices such as thermopiles, bolometers and pyroelectric detectors. These thermal IR detectors operate in a two-step process: (a) the absorption of the IR radiation changes the device temperature; and (b) the change in device temperature changes some other parameter in the device such as a voltage, resistance or electrical polarization that is then converted to an electrical signal. Since these thermal IR detectors operate based on the absorption of the IR radiation changing the device temperature the output signal thus depends on radiant power rather than on the signal wavelength or spectral contents. Their main advantages are in the avoidance of cryogenic cooling requirements and in a relatively simple manufacturing process. Hence these detectors are lightweight, compact, exhibit low power consumption and are moderately priced. Their main disadvantages include: a limited performance range as exhibited by their slow response time; moderate detectivity; and a necessity for vacuum packaging and thermal insulation. The requirement for vacuum packaging and thermal isolation of the sensitive elements required for appropriate detectivity adds significantly to the cost of thermal IR detectors.

Photon or quantum IR detectors, including intrinsic, extrinsic, photo-emissive, quantum-well IR photo-detector (QWIP) and quantum-dot JR photo-detectors (QDIP) generate an output signal that is proportional to the number of photons absorbed in the device material rather than to their total energy. The energy of each single photon which is to be detected must be high enough to cause delocalization of carriers across the device structure, resulting in increasing the device conductivity in the case of photoconductive detectors or in generating a potential difference across a junction in the case of photovoltaic detectors. These detectors are characterized by selective wavelength dependent response. Their main advantages are in improved performance, mostly as regards to their fast response time, and excellent signal-to-noise ratio. However, in order to achieve these advantages for MWIR and LWIR they require cryogenic cooling. The cryogenic cooling reduces thermal noise by preventing thermal generation of free carriers that would compete with the optically-generated carriers. Consequently, photon or quantum IR detectors are characterized by their high cost, high power consumption, heavy weight, large size and continuous maintenance requirements.

The best performing photon or quantum IR detectors are intrinsic, i.e. based on narrow bandgap semiconductors, requiring complicated growth techniques. These materials are relatively soft with a low damage threshold and their manufacturing involves delicate processes that impose serious yield limitations in particular for increasing the number of elements in 2-D scanned arrays. The most widely used material is a compound of Mercury (Hg), Cadmium (Cd) and Tellurium (Te) know as MCT, which demonstrates excellent quantum efficiency (>70%) and exhibits a bandgap that is tunable at the manufacturing phase to the desired wavelength by altering the compound structure composition. MCT detectors require cooling to about 77° K for LWIR, and to about 120° K for MWIR. While these devices may be tuned at the manufacturing phase, they are not dynamically tunable.

Another common detector used for MWIR detection is made of Indium Antimonide (InSb). InSb as a near or absolute stoichiometric compound produces highly uniform response, but still requires cooling to 80° K.

Thus, photon or quantum JR detectors of the prior art provide superior performance, essential for high-end applications where performance requirements cannot be compromised; however the combination of manufacturing difficulties and cooling requirements make these detectors quite costly and bulky.

In summary, the enormous potential value of thermal imaging and other IR detector applications has stimulated intensive research over the past several years. Many advances have been achieved, some of which have been translated to commercial products, and some of which are still in development at research laboratories. Improvements in thermal IR detectors were accomplished relatively recently with the development of microbolometers, and in photon IR detectors with the development of the QWIP and QDIP. However, photon detectors still generally require cooling to cryogenic temperatures, which limits their usage due to size, weight and cost. The performance of uncooled microbolometers and other thermal IR detectors limits their use to medium and low end applications and their need for vacuum packaging technology represents a significant barrier that prevents the technology from being a true ‘enabler’ of low cost, mass market applications for commercial and military markets.

U.S. Patent Application Publication S/N 2004/0253759 A1 published Dec. 16, 2004 to Garber et al., entitled “Steady State Non-Equilibrium Distribution of Free Carriers and Photon Energy Up-Conversion Using Same”, the entire contents of which is incorporated herein by reference, is addressed to methods and specialized media adapted to the formation of a steady state, non-equilibrium distribution of free carriers using mesoscopic classical confinement. In one embodiment an IR to visible light imaging system is implemented using a two step process. First, the IR light being imaged is upconverted to visible light and second, the visible light is detected and converted to an electrical signal. The upconversion is associated with a pumping light and radiative recombination centers. The visible light detection is associated with an optical imaging system arranged to receive the radiative recombinant light. Such a system advantageously provides high quality room temperature infra-red detection, however the requirement for an additional component to sense the radiative recombination adds cost.

There is thus a need for a high quality IR. photo-detector operable at room temperature. Preferably, the IR photo-detector will exhibit superior performance at affordable cost for high end applications, and solid performance at very low cost for mass market applications.

### SUMMARY

Accordingly, it is a principal object of the present invention to overcome at least some of the disadvantages of prior art photo-detectors, particularly the requirement for a low operating temperature to achieve superior performance. This is provided by mesoscopic classical confinement of non-equilibrium carriers, the non-equilibrium carriers being induced by a pumping light source. The non-equilibrium carriers absorb IR radiation from the imaging target and the IR quanta delocalize the confined non-equilibrium carriers into the surrounding material. An electric field moves the charged delocalized free carriers towards provided electrodes and creates an electrical signal proportional to the number of incident IR quanta.

The mesoscopic classical confinement is in certain embodiments enabled by providing a composite media, the composite media being constituted of a plurality of mesoscopic sized inclusions dispersed within a host material, also known as a matrix material. The energy bandgap of the host matrix material is wider than the energy bandgap of the mesoscopic sized inclusions. Each of the mesoscopic sized inclusions and the host matrix material preferably exhibit low electrical conductivity, also known as high electrical resistance, characterized by a negligibly small number of free carriers at dark conditions. The composite media is inserted into an electrical field, which is preferably externally applied. In one embodiment the composite media is inserted between two conductive electrodes. In another embodiment the composite media serves as the intrinsic region of a PIN structure.

The non-equilibrium carriers are initially induced by an external pumping light source, which in a preferred embodiment comprises a monochromatic low power, high energy light source. Preferably, the pumping light is absorbed only within the mesoscopic sized inclusions, while the host matrix material of the composite media is transparent to these photons. The non-equilibrium carriers are confined within the mesoscopic sized inclusions despite their being highly energized by pumping source quanta. The energy barrier of the interface between the mesoscopic sized inclusions and the host matrix material limits the movement of carriers to be within the mesoscopic sized inclusion and prevents their penetration into the host matrix material. The pumping light by itself does not change the conductivity of the host matrix material. The pumping light photon energy determines the maximum of the energetic distribution of free carriers and the spectral width of the pumping light defines the width of the energy distribution of the non-equilibrium free carriers. In the embodiment in which the pumping light comprises a monochromatic pumping light, the energy distribution of the non-equilibrium carriers exhibits a narrowly focused columnar distribution which is thermally uncoupled from the matrix material. From this point of view the atomic lattice of the host matrix material and non-equilibrium carriers are thermodynamically uncoupled. Thus, as long as the energy distribution remains narrowly focused, non-equilibrium carriers are unable to exit the mesoscopic sized inclusions in the absence of the appropriate IR energy thereby minimizing dark noise, irrespective of the operating temperature of the matrix material.

Under the pumping light illumination the composite media becomes IR. sensitive. This phenomenon is known as photo-induced IR free carrier absorption, which due to the fractal structure of the composite media is quite strong. The non-equilibrium carriers, excited by IR photons, are emitted over the energy barrier into the host matrix material where they freely move under the influence of the applied electrical field. The appearance of free carriers within the host matrix material results in increasing the device conductivity in the case of a photoconductive detector or in generating potential difference across a junction in the case of a photovoltaic detector.

The signal to noise ratio of the inventive device is improved due to two main factors. First, in spite of the small stationary concentration of non-equilibrium carriers inside the mesoscopic sized inclusions, the rate of free carrier emission over the barrier is large enough due to the strong IR absorption. Second, as described above, the narrow columnar distribution prevents dark noise.

In one embodiment a photo-detector is provided comprising: a p-doped semiconductor layer; an intrinsic amorphous silicon layer adjacent the p-doped semiconductor layer, the intrinsic amorphous silicon layer comprising a plurality of mesoscopic sized particles of crystalline silicon; and an n-doped semiconductor layer adjacent the intrinsic amorphous silicon layer.

In one further embodiment the photo-detector further comprises a pumping light source in optical communication with the intrinsic amorphous silicon layer, the pumping light source outputting a pumping light exhibiting a wavelength and an intensity operative to produce energized carriers confined within the mesoscopic sized particles. In one yet further embodiment wherein the mesoscopic sized particles release the energized carriers responsive to infra-red light exhibiting a wavelength of 3-5 μm and/or 8-14 μm, the detected wavelength of infra-red light is dependent on the wavelength of the pumping light. In another yet further embodiment the mesoscopic sized particles release the energized carriers responsive to infra-red light exhibiting a wavelength of any sub-band of infra-red light, the wavelength of infra-red light being responsive to the wavelength of the pumping light.

In one further embodiment the mesoscopic sized particles are constituted so as to exhibit classical mesoscopic confinement for energized carriers of a particular energy pre-determined by the pumping light wavelength energy. In another further embodiment the mesoscopic sized particles release the energized carriers responsive to photons characteristic of infra-red light into the surrounding material. In yet another further embodiment the photo-detector further comprises a window in optical communication with the intrinsic amorphous silicon layer and arranged to pass light from a target object.

In one embodiment a plurality of photo-detectors as described above are arranged in an array.

In another embodiment a photo-detector is provided comprising: a p-doped semiconductor layer; an n-doped semiconductor layer adjacent the p-doped semiconductor layer forming a depletion region; and a plurality of mesoscopic sized particles within the depletion region.

In one further embodiment the mesoscopic sized particles are constituted of crystalline silicon.

In one further embodiment the photo-detector further comprises a pumping light source in optical communication with the depletion region, the pumping light source outputting a pumping light exhibiting a wavelength and an intensity operative to produce energized carriers confined within the mesoscopic sized particles. In one yet further embodiment the mesoscopic sized particles release the energized carriers responsive to infra-red light exhibiting a wavelength of 3-5 μm or 8-14 μm, the wavelength of infra-red light being responsive to the wavelength of the pumping light. In another yet further embodiment the mesoscopic sized particles release the energized carriers responsive to infra-red light exhibiting a wavelength of any sub-band of infra-red light, the wavelength of infra-red light being responsive to the wavelength of the pumping light.

In one further embodiment the mesoscopic sized particles are constituted so as to exhibit classical mesoscopic confinement for energized carriers of a pre-determined energy. In another further embodiment the mesoscopic sized particles release the energized carriers responsive to photons characteristic of infra-red light. In yet another further embodiment the photo-detector further comprises a window in optical communication with the depletion region and arranged to pass light from a target object.

In one embodiment the invention provides for a plurality of photo-detectors as described above arranged in an array.

In one embodiment a method of photo-detection is provided comprising:

providing mesoscopic sized particles in one of: an intrinsic semiconductor layer sandwiched between a p-semiconductor and an n-semiconductor, and a depletion region formed between a p-semiconductor juxtaposed with an n-semiconductor; receiving a pumping light at the provided mesoscopic sized particles, the received pumping light energizing free carriers to an energy level for confinement within the mesoscopic sized particles; and receiving light of a target waveband, the received light further energizing the free carriers to be released from the confinement. In one further embodiment the provided mesoscopic sized particles are constituted of crystalline silicon. In another further embodiment, the method further comprises reverse biasing the semiconductor PN junction. Preferably the p-semiconductor and n-semiconductor are constituted of a doped amorphous silicon.

In one further embodiment the pumping light exhibits a wavelength and an intensity operative to produce the energized carriers confined within the mesoscopic sized particles. In one yet further embodiment the method further comprises: providing the received pumping light; and selecting the wavelength of the provided pumping light so as to select the target waveband to be a particular sub-band of infra-red wavelengths.

In one further embodiment the target waveband is selected from the group consisting of 3-5 μm and/or 8-14 μm. In another further embodiment the provided mesoscopic sized particles are constituted so as to exhibit classical mesoscopic confinement for the energized free carriers of a pre-determined energy.

In one further embodiment the method further comprises detecting the free carriers released from the confinement. In another further embodiment the method further comprises detecting the free carriers released from the confinement thereby imaging a target radiating the received light of the target waveband.

In one embodiment a photo-detector is provided comprising: a p-doped semiconductor layer; an n-doped semiconductor layer juxtaposed with the p-doped semiconductor layer; one of an intrinsic amorphous silicon layer sandwiched between the p-doped semiconductor layer and the n-doped semiconductor layer and a depletion region formed between the p-doped semiconductor layer juxtaposed with the n-doped semiconductor layer; and a plurality of mesoscopic sized particles within the one of the intrinsic amorphous silicon layer sandwiched between the p-doped semiconductor layer and the n-doped semiconductor layer and the depletion region formed between the p-doped semiconductor layer juxtaposed with the n-doped semiconductor layer. In one further embodiment the mesoscopic sized particles are constituted of crystalline silicon.

Additional features and advantages of the invention will become apparent from the following drawings and description.

### BRIEF DESCRIPTION OF THE DRAWINGS

For a better understanding of various embodiments of the invention and to show how the same may be carried into effect, reference will now be made, purely by way of example, to the accompanying drawings in which like numerals designate corresponding elements or sections throughout.

With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the accompanying drawings:

FIG. 1 illustrates a high level schematic view of a cross section of a PIN junction photo-detector according to certain embodiments;

FIG. 2 illustrates a high level schematic view of a cross section of a PN junction photo-detector according to certain embodiments;

FIG. 3 illustrates the energy band levels experienced by a carrier in the photo-detectors of FIGS. 1 and 2;

FIG. 4A illustrates a schematic side view of a photo-detector assembly according to certain embodiments including a pumping light;

FIG. 4B illustrates a schematic top view of the photo-detector assembly of FIG. 4A according to certain embodiments including a pumping light; and

FIG. 5 illustrates steps in the method of detecting light of the target waveband in accordance with a certain embodiments.

### DETAILED DESCRIPTION

Certain of the present embodiments enable an improved photo-detector responsive to the IR waveband preferably operating at room temperature comprising a PN junction or a PIN junction, exhibiting a plurality of mesoscopic sized particles within a respective one of the depletion region and an intrinsic silicon layer. A pumping light and a means for receiving the pumping light in optical communication with the pumping light is further provided. The mesoscopic sized particles are comprised of a different composition than the surrounding material, and exhibit mesoscopic classical confinement for free carriers energized by the received pumping light. The pumping light is of a wavelength and intensity arranged to generate free carriers exhibiting an energy level for confinement within the mesoscopic particles. Light energy of the target waveband, different from the pumping light waveband, releases the free carriers from confinement and generates a current within the photo-detector. The total energy of two photons, i.e. the pumping light energy and the target band light energy, is sufficient to release carriers from the confinement of the mesoscopic size particles to the surrounding material.

Preferably the target waveband is an IR waveband, and further preferably the target waveband is the MWIR waveband.

The term mesoscopic sized as used within this document refers to a size greater than the wavelength of an electron in the material, but less than the momentum relaxation length of free carriers within the material. Practically, the term mesoscopic is understood to mean greater than 10 nm but less than 1 micron, and preferably between 50 nm and 500 nm.

The term wide band-gap, as used within this document, refers to the size of the band-gap in relation to the band-gap of the constituent material of the mesoscopic sized particles. In one embodiment, the mesoscopic sized particles are constituted of crystalline silicon, thus exhibiting a band-gap of about 1.12 eV. The surrounding material thus exhibits a wide band-gap provided that it exhibits a band gap greater than 1.12 eV. In one embodiment the surrounding material is constituted of amorphous silicon, doped or intrinsic, with an intrinsic band-gap of about 1.75 eV.

Before explaining at least one embodiment in detail, it is to be understood that the invention is not limited in its application to the details of construction and the arrangement of the components set forth in the following description or illustrated in the drawings. The invention is applicable to other embodiments or of being practiced or carried out in various ways. Also, it is to be understood that the phraseology and terminology employed herein is for the purpose of description and should not be regarded as limiting.

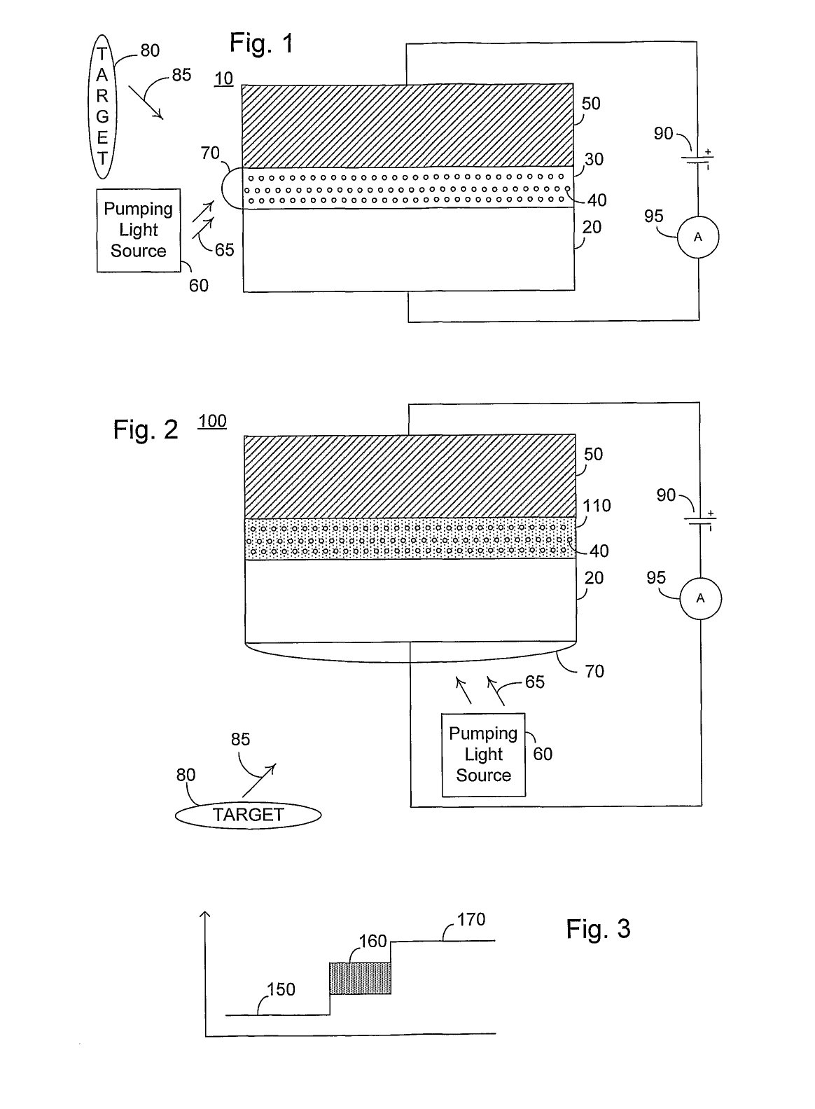

FIG. 1 illustrates a high level schematic view of a cross section of an embodiment of a PIN junction photo-detector 10, comprising: a p-doped semiconductor layer 20; an intrinsic semiconductor layer 30 comprising a plurality of mesoscopic sized particles 40: an n-doped semiconductor layer 50; a pumping light source 60 generating a pumping light 65; and a window 70. Also depicted is a target 80, radiating a target waveband light 85 which is to be detected, and an electrical potential 90 and a current flow indicator 95.

Intrinsic semiconductor layer 30 is adjacent to, and sandwiched between, p-doped semiconductor layer 20 and n-doped semiconductor layer 50. In one embodiment, each of intrinsic semiconductor layer 30, p-doped semiconductor layer 20 and n-doped semiconductor layer 50 are constituted of amorphous silicon, intrinsic or doped as required. In one further embodiment mesoscopic sized particles 40 are constituted of crystalline silicon. Window 70 is arranged to allow both pumping light 65 and target waveband light 85 to be received by intrinsic semiconductor layer 30. In one embodiment window 70 comprises a lens covering a portion of intrinsic semiconductor layer 30, as depicted. In another embodiment window 70 comprises one of a lens and a window arranged to focus or pass pumping light 65 generated by pumping light source 60 and target waveband light 85 to one of p-doped semiconductor layer 20 and n-doped semiconductor layer 50, which are substantially transparent to pumping light 65 and target waveband light 85, and thus pumping light 65 and target waveband light 85 are passed to intrinsic semiconductor layer 30. There is no requirement that a single lens or window be used, and the use of separate windows or lenses for the pumping light 65 and target waveband light 85 are specifically contemplated without exceeding the scope of the invention. Electrical potential 90 is arranged with its positive side connected to n-doped semiconductor layer 50 and its negative side connected via current flow indicator 95 to p-doped semiconductor layer 20. Thus, PIN junction photo-detector 10 is reverse biased.

In one embodiment intrinsic semiconductor layer 30 comprises amorphous silicon and mesoscopic sized particles 40 are constituted of crystalline silicon. In another embodiment intrinsic semiconductor layer 30 comprises one of crystalline silicon and amorphous silicon, and mesoscopic sized particles 40 are constituted of a material exhibiting classical confinement for free carriers energized by pumping light 65. Pumping light source 60 is arranged to generate pumping light 65 exhibiting the appropriate wavelength and intensity to generate free carriers confined within mesoscopic sized particles 40. The free carriers, upon receiving energy from target waveband light 85 are further energized to the conduction band of one of p-doped semiconductor layer 20 and n-doped semiconductor layer 50 and are detected by current flow indicator 95. Changing the wavelength of pumping light 65 adjusts the wavelength of light from target 80 for which carriers are energized into the conduction band of one of p-doped semiconductor layer 20 and n-doped semiconductor layer 50. Thus, PIN junction photo-detector 10 is dynamically tunable over a range of wavelengths.

FIG. 2 illustrates a high level schematic view of a cross section of an embodiment of a PN junction photo-detector 100, comprising: a p-doped semiconductor layer 20; an n-doped semiconductor layer 50 in contact with p-doped semiconductor layer 20 forming a depletion region 110; a plurality of mesoscopic sized particles 40 within depletion region 110; a pumping light source 60 generating a pumping light 65; and a window 70. Also depicted is a target 80, radiating a target waveband light 85 which is to be detected, an electrical potential 90 and a current flow indicator 95. In one embodiment, each of p-doped semiconductor layer 20 and n-doped semiconductor layer 50 are constituted of amorphous silicon, doped as required. In one further embodiment mesoscopic sized particles 40 are constituted of crystalline silicon.

Window 70 is arranged to allow both pumping light 65 and target waveband light 85 to be received at depletion region 110. In one embodiment, as depicted, window 70 comprises one of a lens and a window arranged to focus or pass pumping light 65 generated by pumping light source 60 and target waveband light 85 to p-doped semiconductor layer 20 which is substantially transparent to pumping light 65 and target waveband light 85, and thus pumping light 65 and target waveband light 85 are passed to depletion region 110. In another embodiment (not shown), window 70 comprises one of a lens and a window arranged to focus or pass pumping light 65 generated by pumping light source 60 and target waveband light 85 to n-doped semiconductor layer 50 which is substantially transparent to pumping light 65 and target waveband light 85, and thus pumping light 65 and target waveband light 85 are passed to depletion region 110. In yet another embodiment, as described above in relation to FIG. 1, window 70 comprises a lens covering a portion of depletion region 110. There is no requirement that a single lens or window be used, and the use of separate windows or lenses for the pumping light 65 and target waveband light 85 are specifically contemplated without exceeding the scope of the invention. Electrical potential 90 is arranged with its positive side connected to n-doped semiconductor layer 50 and its negative side connected via current flow indicator 95 to p-doped semiconductor layer 20. Thus, PN junction photo-detector 100 is reverse biased.

In one embodiment mesoscopic sized particles 40 are constituted of a material exhibiting classical confinement for free carriers energized by the pumping light source 60. The free carriers, upon receiving energy from target 80, radiating a target waveband light 85, are further energized to the conduction band of one of p-doped semiconductor layer 20 and n-doped semiconductor layer 50. Pumping light source 60 is arranged to generate pumping light 65 exhibiting the appropriate wavelength and intensity to generate free carriers confined within mesoscopic sized particles 40. The free carriers, upon receiving energy from target waveband light 85 are further energized to the conduction band of one of p-doped semiconductor layer 20 and n-doped semiconductor layer 50 and are detected by current flow indicator 95. Changing the wavelength of pumping light 65 adjusts the wavelength of light from target 80 for which carriers are energized into the conduction band of one of p-doped semiconductor layer 20 and n-doped semiconductor layer 50. Thus, PN junction photo-detector 110 is dynamically tunable over a range of wavelengths.

FIG. 3 illustrates the energy band levels experienced by a carrier in the photo-detectors of FIGS. 1 and 2 exhibiting: a region 150 corresponding to the valence band energy of intrinsic semiconductor layer 30 of PIN junction photo-detector 10 of FIG. 1 or depletion layer 110 of PN junction photo-detector 100 of FIG. 2; a region 160 corresponding to a plurality of energy bands within each mesoscopic sized particle 40; and a region 170 corresponding to the conduction band energy of one of p-doped semiconductor layer 20 and n-doped semiconductor layer 50 of FIGS. 1, 2, respectively. Pumping light energy received from pumping light source 60 energizes free carriers to the energy level of region 160 where they are confined. Target waveband light 85, representing energy to be detected, further energizes free carriers confined within region 160 to the band energy characteristic of region 170.

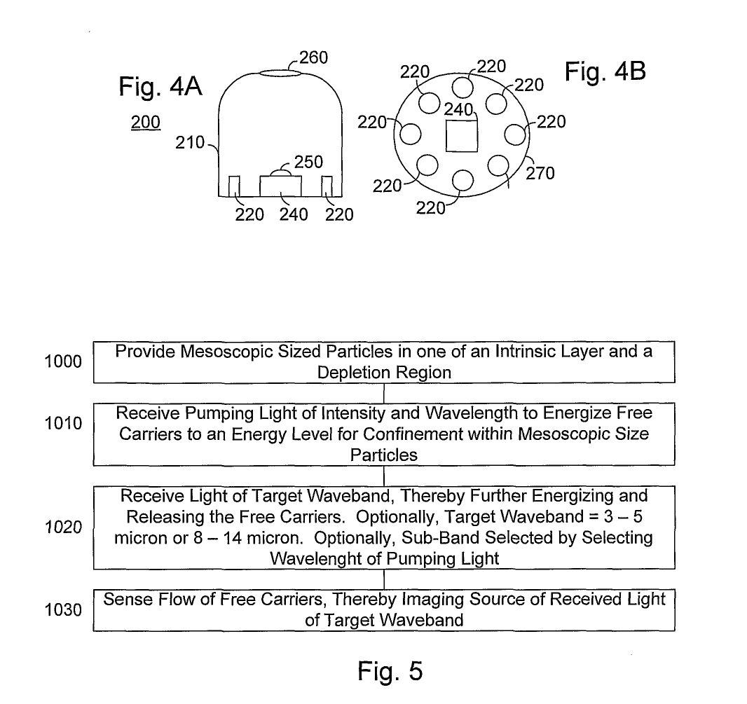

FIG. 4A illustrates a schematic side view of a photo-detector assembly 200 comprising: a housing 210; a plurality of light sources 220: a photo-detector array 240 exhibiting a lens 250: and a window for receiving target waveband light 260. Preferably, window for receiving target waveband light 260 comprises a lens, and further preferably window for receiving target waveband light 260 exhibits a filter arranged to selectively pass light of the target waveband.

Housing 210 is arranged to secure window for receiving target waveband light 260 so as to pass, and preferably focus, light received from the target 80 to photo-detector 240 via lens 250. Housing 210 is further arranged to reflect pumping light from the plurality of light sources 220 to be received by detector 240 via lens 250. Photo-detector array 240 preferably comprises an array of photo-detectors each in accordance with one of PIN junction photo-detector 10 of FIG. 1 and PN junction photo-detector 100 of FIG. 2. The array may be linear or a 2 dimensional array without exceeding the scope of the invention. In one further embodiment, amplifiers are further provided connected to each constituent photo-detector of photo-detector array 240 to electrically amplify the resultant signal. The amplifiers may be provided within photo-detector array 240, or external to photo-detector array 240, without exceeding the scope of the invention.

FIG. 4B illustrates a schematic top view of the photo-detector assembly of FIG. 4A, comprising: a housing base 270, plurality of light sources 220 and photo-detector array 240. Housing base 270 functions to secure the plurality of light sources 220 in proper alignment with photo-detector 240.

FIG. 5 illustrates steps in the generation of confined free carriers and the detection of light of the target waveband. In stage 1000, mesoscopic sized particles 40 are provided within one of intrinsic layer 30 and depletion region 110 of FIGS. 1 and 2 respectively. In stage 1010, a pumping light is received, preferably provided by a pumping light source 60 via window 70 of FIG. 1, 2, or lens 250 of FIG. 4A. The received pumping light exhibits appropriate energy and intensity to energize free carriers to an energy level consonant with confinement within the provided mesoscopic sized particles of stage 1000. Preferably, the confinement is classical confinement.

In stage 1020, light of a target waveband to be detected is received, preferably from a target object such as target object 80. The received target waveband light further energizes the confined energized free carriers of stage 1010, and releases the further energized carriers from confinement. Optionally, the target waveband is one of 3-5 μm and 8-14 μm. In one embodiment the wavelength of the pumping light of stage 1010 is selected so as to determine a particular target sub-band.

In stage 1030, the released further energized carriers of stage 1020 are detected as part of an electrical flow, thereby imaging the source of the received light of the target waveband. In one embodiment, as described above in relation to FIG. 1 and FIG. 2, the PN or PIN junction is reverse biased, and thus current flow is primarily responsive to the released further energized carriers.

Thus certain of the present embodiments enable an improved photo-detector responsive to the IR waveband preferably operating at room temperature comprising a PN junction or a PIN junction, exhibiting a plurality of mesoscopic sized particles within a respective one of the depletion region and an intrinsic silicon layer. A pumping light and a means for receiving the pumping light in optical communication with the pumping light is further provided. The mesoscopic sized particles are comprised of a different composition than the surrounding material, and exhibit mesoscopic classical confinement for free carriers energized by the received pumping light. The pumping light is of a wavelength and intensity arranged to generate free carriers exhibiting an energy level for confinement within the mesoscopic particles. Light energy of the target waveband, different from the pumping light waveband, releases the free carriers from confinement and generates a current within the photo-detector.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

Unless otherwise defined, all technical and scientific terms used herein have the same meanings as are commonly understood by one of ordinary skill in the art to which this invention belongs. Although methods similar or equivalent to those described herein can be used in the practice or testing of the present invention, suitable methods are described herein.

All publications, patent applications, patents, and other references mentioned herein are incorporated by reference in their entirety. In case of conflict, the patent specification, including definitions, will prevail. In addition, the materials, methods, and examples are illustrative only and not intended to be limiting.

It will be appreciated by persons skilled in the art that the present invention is not limited to what has been particularly shown and described hereinabove. Rather the scope of the present invention is defined by the appended claims and includes both combinations and sub-combinations of the various features described hereinabove as well as variations and modifications thereof, which would occur to persons skilled in the art upon reading the foregoing description.

1. A photo-detector comprising:
a p-doped semiconductor layer;
an intrinsic amorphous silicon layer adjacent said p-doped semiconductor layer, said intrinsic amorphous silicon layer comprising a plurality of mesoscopic sized particles of crystalline silicon; and
an n-doped semiconductor layer adjacent said intrinsic amorphous silicon layer.

2. A photo-detector according to claim 1, further comprising a pumping light source in optical communication with said intrinsic amorphous silicon layer, said pumping light source outputting a pumping light exhibiting a wavelength and an intensity operative to produce energized carriers confined within said mesoscopic sized particles.

3. (canceled)

4. (canceled)

5. A photo-detector according to claim 1, wherein said mesoscopic sized particles are constituted so as to exhibit classical mesoscopic confinement for energized carriers of a pre-determined energy.

6. (canceled)

7. A photo-detector according to claim 1 further comprising a window in optical communication with said intrinsic amorphous silicon layer and arranged to pass light from a target object.

8. (canceled)

9. A photo-detector comprising:
a p-doped semiconductor layer;
an n-doped semiconductor layer adjacent said p-doped semiconductor layer forming a depletion region; and
a plurality of mesoscopic sized particles within said depletion region.

10. A photo-detector according to claim 9, wherein said mesoscopic sized particles are constituted of crystalline silicon.

11. A photo-detector according to claim 9, further comprising a pumping light source in optical communication with said depletion region, said pumping light source outputting a pumping light exhibiting a wavelength and an intensity operative to produce energized carriers confined within said mesoscopic sized particles.

12. (canceled)

13. (canceled)

14. A photo-detector according to claim 9, wherein said mesoscopic sized particles are constituted so as to exhibit classical mesoscopic confinement for energized carriers of a pre-determined energy.

15. (canceled)

16. A photo-detector according to claim 9, further comprising a window in optical communication with said depletion region and arranged to pass light from a target object.

17. (canceled)

18. A method of photo-detection comprising:
providing mesoscopic sized particles in one of: an intrinsic semiconductor layer sandwiched between a p-semiconductor and an n-semiconductor, and a depletion region formed between a p-semiconductor juxtaposed with an n-semiconductor;
receiving a pumping light at said provided mesoscopic sized particles, said received pumping light energizing free carriers to an energy level for confinement within said mesoscopic sized particles; and
receiving light of a target waveband, said received light further energizing said free carriers to be released from said confinement.

19. A method according to claim 18, wherein said provided mesoscopic sized particles are constituted of crystalline silicon.

20. A method according to claim 18, further comprising reverse biasing said p-semiconductor and said n-semiconductor.

21. A method according to claim 18, wherein said pumping light exhibits a wavelength and an intensity operative to produce said energized carriers confined within said mesoscopic sized particles.

22. A method according to claim 21, further comprising:
providing said received pumping light; and
selecting the wavelength of said provided pumping light so as to select the target waveband to be a particular sub-band of infra-red wavelengths.

23. A method according to claim 18, wherein said target waveband is selected from the group consisting of 3-5 μm and 8-14 μm.

24. A method according to claim 18, wherein said provided mesoscopic sized particles are constituted so as to exhibit classical mesoscopic confinement for said energized free carriers of a pre-determined energy.

25. A method according to claim 18, further comprising detecting said free carriers released from said confinement.

26. A method according to claim 18, further comprising detecting said free carriers released from said confinement thereby imaging a target radiating said received light of said target waveband.

27. A photo-detector comprising:
a p-doped semiconductor layer;
an n-doped semiconductor layer juxtaposed with said p-doped semiconductor layer;
one of an intrinsic amorphous silicon layer sandwiched between said p-doped semiconductor layer and said n-doped semiconductor layer and a depletion region formed between said p-doped semiconductor layer juxtaposed with said n-doped semiconductor layer; and
a plurality of mesoscopic sized particles within said one of said intrinsic amorphous silicon layer sandwiched between said p-doped semiconductor layer and said n-doped semiconductor layer and said depletion region formed between said p-doped semiconductor layer juxtaposed with said n-doped semiconductor layer.

28. A photo-detector according to claim 27, wherein said mesoscopic sized particles are constituted of crystalline silicon.
